(19) United States
(12) Patent Application Publication
(10) Pub. No.: US 2025/0030397 A1
(43) Pub. Date: Jan. 23, 2025

(54) SURFACE ACOUSTIC WAVE DEVICE HAVING IMPROVED Q PERFORMANCE AND METHOD OF MANUFACTURING THE SAME

(71) Applicant: WISOL CO., LTD., Osan-si (KR)

(72) Inventors: Yoshikazu KIHARA, Osan-si (KR); Hun Yong LEE, Osan-si (KR); Chang Min LEE, Osan-si (KR)

(21) Appl. No.: 18/765,294

(22) Filed: Jul. 7, 2024

(30) Foreign Application Priority Data
Jul. 18, 2023 (KR) 10-2023-0093382

(51) Int. Cl. H03H 9/02; H03H 3/08; H03H 9/25

(52) U.S. Cl. CPC H03H 9/02866; H03H 3/08; H03H 9/25

(57) ABSTRACT

A Surface Acoustic Wave (SAW) device having improved Q performance and high reliability of a bonding unit and a method of manufacturing the same are provided. The surface acoustic wave device includes a support substrate; a high sound velocity layer formed on the support substrate; a first low sound velocity layer formed on the high sound velocity layer; a second low sound velocity layer formed on the first low sound velocity layer; a piezoelectric plate formed on the second low sound velocity layer; and a plurality of IDT electrode fingers formed on the piezoelectric plate, and the sound velocity of the first low sound velocity layer and the sound velocity of the second low sound velocity layer are different from each other.

### BACKGROUND OF THE INVENTION

### Field of the Invention

The present invention relates to a surface acoustic wave (SAW) device having improved Q performance and a method of manufacturing the same, and more specifically, to a surface acoustic wave (SAW) device configuring a plurality of low sound velocity layers and a method of manufacturing the same.

### Background of the Related Art

A Surface Acoustic Wave (SAW) refers to a wave that propagates along the surface of an elastic solid, and the surface acoustic wave propagates with energy concentrated near the surface and corresponds to a mechanical wave. The surface acoustic wave device is an electromechanical device that utilizes interactions between the surface acoustic waves and conduction electrons, and uses surface acoustic waves transferred to the surface of a piezoelectric crystal. The surface acoustic wave device may have a very wide range of industrial applications, including sensors, oscillators, filters, and the like, and may be miniaturized and lightweighted to have various advantages such as robustness, stability, sensitivity, low cost, real-time property, and the like.

In order to obtain a high Q value as a surface acoustic wave device that requires high performance, a structure of stacking a high sound velocity layer 110 and a low sound velocity layer 120 between a piezoelectric plate 130 and a support substrate 100 as shown in FIG. 1 has been applied.

Non-patent document 0001 discloses a result of confining SAW energy within 2 Lambda from the surface using one high sound velocity layer and one low sound velocity layer as shown in FIG. 1. Patent Document 0001 discloses a surface acoustic wave device configured of one piezoelectric body, one low sound velocity layer, one high sound velocity layer, and a support substrate, and may trap surface acoustic wave energy in the low sound velocity layer and the piezoelectric body by reducing the thickness of the piezoelectric body to 1.5 Lambda or less.

Referring to FIG. 1, the surface acoustic wave device according to the prior art is configured by forming a high sound velocity layer 110 and a low sound velocity layer 120 on a support substrate 100, and bonding the low sound velocity layer 120 and the piezoelectric plate 130. At this point, the support substrate 100 is made of single crystal Si or sapphire, the high sound velocity layer 110 is made of aSi, PolySi, SiN, or AlN, the low sound velocity layer 120 is made of SiO₂, and the piezoelectric plate 130 is made by bonding a single crystal LiTaO₃ (LT) and then thinning it. In this structure, surface acoustic wave energy is concentrated on the piezoelectric plate 130 made of LT and the low sound velocity layer 120 made of SiO₂, and energy leakage to the high sound velocity layer 110 or the support substrate 100 is ignorable.

Generally, it is difficult to change the viscosity of the single crystal LiTaO₃ constituting the piezoelectric plate 130. In addition, SiO₂ is used in the low sound velocity layer 120, and this is generally manufactured by a Chemical Vapor Deposition (CVD) device, is amorphous, has various crystal structures and porosity, and has various viscosities according to the conditions at the time of deposition. The viscosity is greater when the low sound velocity layer 120 is manufactured using a Physical Vapor Deposition (PVD) device. Distribution of high viscosity of the low sound velocity layer 120 of the prior art structure has a problem of deteriorating Q performance of the surface acoustic wave device.
(Patent Document 1) JP5910763B2
(Non-patent Document 1) Incredible high performance SAW resonator on novel multi-layered substrate (2016 IEEE International Ultrasonics Symposium (IUS))

### SUMMARY OF THE INVENTION

Therefore, the present invention has been made in view of the above problems, and it is an object of the present invention to provide a surface acoustic wave device that can stably implement a high Q value and a method of manufacturing the device.

The technical problems of the present invention are not limited to the technical problems mentioned above, and unmentioned other technical problems will be clearly understood by those skilled in the art from the following description.

To accomplish the above object, according to one aspect of the present invention, there is provided a surface acoustic wave device
comprising: a support substrate; a first low sound velocity layer formed directly or indirectly on the support substrate; at least one second low sound velocity layer formed on the first low sound velocity layer; a piezoelectric plate formed on the second low sound velocity layer; and a plurality of IDT electrode fingers formed on the piezoelectric plate, wherein the sound velocity of the first low sound velocity layer and the sound velocity of the second low sound velocity layer are different from each other.

In some embodiments of the invention, the first low sound velocity layer and the second low sound velocity layer may include the same material.

In some embodiments of the invention, the first low sound velocity layer and the second low sound velocity layer may include an SiO₂ material.

In some embodiments of the invention, the second low sound velocity layer may have a sound velocity higher than that of the first low sound velocity layer.

In some embodiments of the invention, the second low sound velocity layer may have a density higher than that of the first low sound velocity layer.

In some embodiments of the invention, the second low sound velocity layer may have stiffness higher than that of the first low sound velocity layer.

In some embodiments of the invention, the second low sound velocity layer may have an O content higher than that of the first low sound velocity layer.

In some embodiments of the invention, a resonance frequency of the surface acoustic wave may be determined by a wavelength λ defined by a pitch of the IDT electrode fingers.

In some embodiments of the invention, thickness of the piezoelectric plate may be 1.5 times or less than the wavelength.

In some embodiments of the invention, the first low sound velocity layer may be formed by Chemical Vapor Disposition (CVD), and the second low sound velocity layer may be formed by Physical Vapor Disposition (PVD).

In some embodiments of the invention, the surface acoustic wave device may further comprise one or more low sound velocity layers between the first low sound velocity layer and the second low sound velocity layer.

According to the surface acoustic wave filter device of the present invention with an improved structure and a manufacturing method thereof, deterioration of Q performance due to high viscosity of a low sound velocity layer in the structure of the prior art can be improved by the low viscosity of a low sound velocity layer (second low sound velocity layer).

The effects of the present invention are not limited to the effects mentioned above, and unmentioned other effects will be clearly understood by those skilled in the art from the description of the claims.

### BRIEF DESCRIPTION OF THE DRAWINGS

FIG. 1 is a view showing a surface acoustic wave device including a high sound velocity layer and a low sound velocity layer according to the prior art.

FIGS. 2A and 2B are views showing a surface acoustic wave device including two or more low sound velocity layers according to an embodiment of the present invention.

FIGS. 3A and 3B are views for explaining the effect of a surface acoustic wave device according to an embodiment of the present invention.

FIGS. 4 to 9 are views for explaining a method of manufacturing a surface acoustic wave device including two or more low sound velocity layers according to an embodiment of the present invention.

### DETAILED DESCRIPTION OF THE PREFERRED EMBODIMENT

The advantages and features of the present invention and the method for achieving them will become clear by referring to the embodiments described below in detail together with the accompanying drawings. However, the present invention is not limited to the embodiments disclosed below and will be implemented in various different forms. The embodiments are provided only to make the disclosure of the present invention complete and to fully inform those skilled in the art of the scope of the present invention, and the present invention is only defined by the scope of the claims. Like reference numerals refer to like elements throughout the specification.

“And/or” includes each of the mentioned items and all combinations of one or more of the mentioned items.

The terms used in this specification are intended to describe the embodiments and are not to limit the present invention. In this specification, singular forms also include plural forms unless specially stated otherwise in the phrases. The terms “comprises” and/or “comprising” used in this specification means that the mentioned components, steps, operations, and/or elements do not exclude the presence or addition of one or more other components, steps, operations and/or elements.

Unless defined otherwise, all the terms (including technical and scientific terms) used in this specification may be used as meanings that can be commonly understood by those skilled in the art. In addition, terms defined in commonly used dictionaries are not interpreted ideally or excessively unless clearly and specially defined.

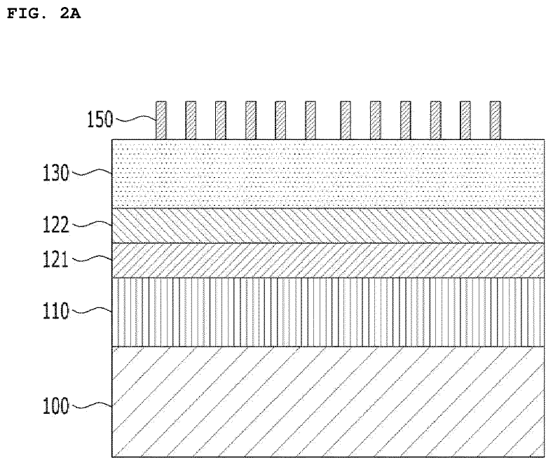

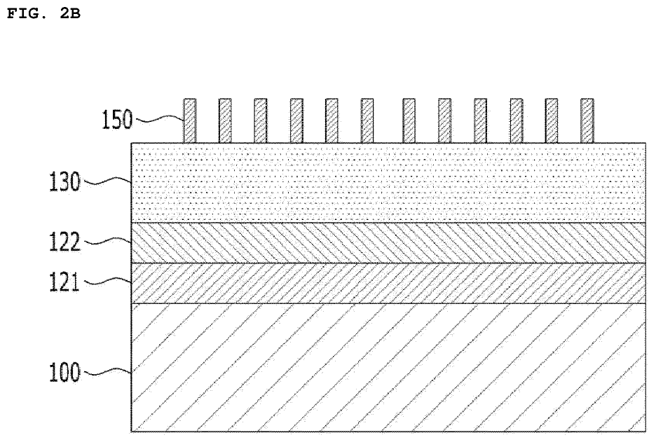

FIGS. 2A and 2B are views showing the structure of a surface acoustic wave device according to an embodiment of the present invention.

First, referring to FIG. 2A, the surface acoustic wave device according to an embodiment of the present invention includes a high sound velocity layer 110 formed on the support substrate 100, a first low sound velocity layer 121, a second low sound velocity layer 122, a piezoelectric plate 130, and a plurality of IDT electrode fingers 150 formed on the piezoelectric plate 130.

Referring to FIG. 2B, the surface acoustic wave device according to an embodiment of the present invention includes a first low sound velocity layer 121 formed directly or indirectly on the support substrate 100, a second low sound velocity layer 122, a piezoelectric plate 130, and a plurality of IDT electrode fingers 150 formed on the piezoelectric plate 130.

The support substrate 100 may have a transverse wave sound velocity higher than the transverse wave sound velocity of the piezoelectric plate 130, and the high sound velocity layer 110 may also have a transverse wave sound velocity higher than the transverse wave sound velocity of the piezoelectric plate 130.

The support substrate 100 may include, for example, a silicon substrate, a sapphire substrate, a silicon carbide (Sic) substrate, a quartz substrate, a glass substrate, and the like.

The high sound velocity layer 110 may be formed on the support substrate 100. The high sound velocity layer 110 may include, for example, amorphous silicon (a-Si), polysilicon (PolySi), silicon nitride (SiN), silicon oxynitride (SiON), aluminum nitride (AlN), boron nitride (BN), diamond, and the like.

The first low sound velocity layer 121 and the second low sound velocity layer 122 may be formed on the support substrate 100 or the high sound velocity layer 110. The sound velocity of the transverse wave propagating through the first low sound velocity layer 121 may be different from that of the second low sound velocity layer 122.

Specifically, the sound velocity of the second low sound velocity layer 122 may be higher than the sound velocity of the first low sound velocity layer 121.

The second low sound velocity layer 122 may have a transverse sound velocity lower than the transverse wave sound velocity of the piezoelectric plate 130, and the first low sound velocity layer 121 may have a sound velocity different from that of the second low sound velocity layer 122. In order for the first low sound velocity layer 121 and the second low sound velocity layer 122 to have different sound velocities, for example, the second low sound velocity layer 122 may have a density higher than that of the first low sound velocity layer 121. Alternatively, stiffness of the second low sound velocity layer 122 may be higher than that of the first low sound velocity layer 121.

Meanwhile, the first low sound velocity layer 121 and the second low sound velocity layer 122 may contain the same material, and for example, although the same SiO₂ is contained, the sound velocity of the second low sound velocity layer 122 may be further increased by increasing the content of oxygen O of the second low sound velocity layer 122. In some embodiments of the present invention, the second low sound velocity layer 122 may also contain argon Ar.

In some embodiments of the present invention, deposition of the first low sound velocity layer 121 and the second low sound velocity layer 122 may be performed in different processes, and specifically, the first low sound velocity layer 121 may be deposited by Chemical Vapor Deposition (CVD), and the second low sound velocity layer 122 may be deposited by Physical Vapor Deposition (PVD). When the second low sound velocity layer 122 is deposited by PVD, the sound velocity and density may be higher and the viscosity may be lower than those of the first low sound velocity layer 121 deposited by CVD. Through this, the second low sound velocity layer 122, of which the sound velocity is higher than that of the first low sound velocity layer 121, may be formed.

The piezoelectric plate 130 may include a piezoelectric element and generate elastic waves from a signal applied to the IDT electrode fingers 150, and may include materials such as LiTaO₃ (LT) and LiNbO₃ (LN).

The resonance frequency of the surface acoustic wave may be determined by the wavelength λ defined by the pitch of the IDT electrode fingers 150. At this point, the piezoelectric plate 130 may be manufactured to have a thickness equal to or smaller than the wavelength A.

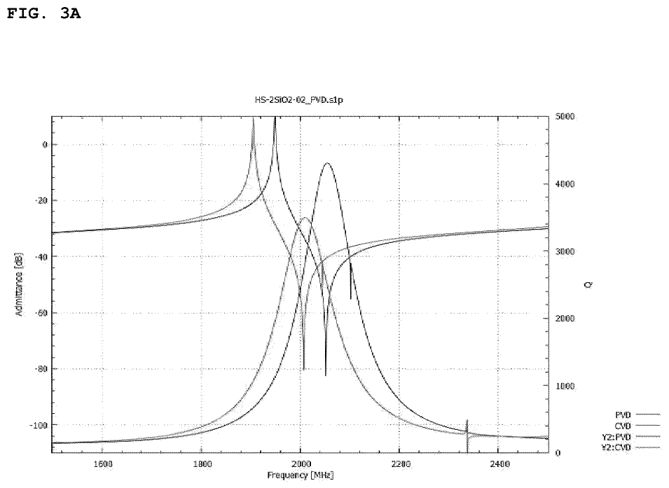

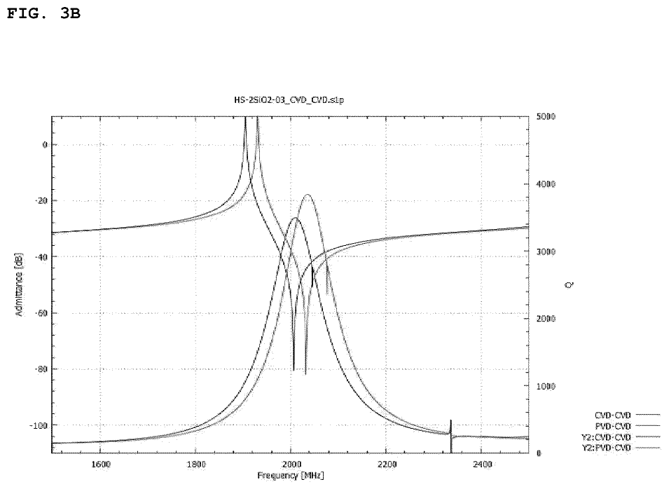

FIGS. 3A and 3B are views for explaining the effect of a surface acoustic wave device according to an embodiment of the present invention.

Referring to FIG. 3A, it is a graph showing the admittance and Q characteristics of a surface acoustic wave device, in which a low sound velocity layer of a single layer is deposited using a CVD device according to the prior art, and a surface acoustic wave device, in which a low sound velocity layer of a single layer is deposited using a PVD device, for comparison. The red graph shows the admittance and Q characteristics of a surface acoustic wave device including a low sound velocity layer deposited by CVD, and the black graph shows the admittance and Q characteristics of a surface acoustic wave device in which a low sound velocity layer is deposited using a PVD device. In the comparative example, LiTaO₃ is used for the piezoelectric plate, SiO₂ is used for the low sound velocity layer, PolySi is used for the high sound velocity layer, and Si is used for the support substrate. When thickness of each layer is standardized to the power of the IDT electrode of the surface acoustic wave device, the piezoelectric plate is 0.3 lambda, the low sound velocity layer is 0.2 lambda, and the high sound velocity layer is 0.2 lambda.

Since the low sound velocity layer deposited using a PVD device has a sound velocity higher than that of the low sound velocity layer deposited using a CVD device, the resonance frequency of the surface acoustic wave device including the low sound velocity layer deposited using a PVD device is higher than the resonance frequency of the surface acoustic wave device including the low sound velocity layer deposited using a CVD device. In addition, since the low sound velocity layer deposited by PVD has a high density and few defects, Q characteristics may also be improved. However, the PVD device has a defect of generating particles as the SiO₂ attached to the film deposition chamber is peeled off due to its structure, and although the chamber is managed by chamber cleaning, generation of about 1,000 particles with a size of 0.2 μm is the realistic lower limit. The particles generated during the deposition are included within the stacking structure of the device and generate void defects or wafer bonding defects, and these defects are likely to increase during a reliability test that involves heating.

In addition, since it needs for the sake of cleaning to release the vacuum in the vacuum device and then open the chamber and physically remove the deposited SiO₂, reducing the work frequency as much as possible during mass production is desirable to lower the manufacturing costs.

On the other hand, the CVD device may clean the inside of the chamber using a gas whenever the deposition is completed and greatly reduce the frequency of occurrence of defects generated by the particles or defects of wafer bonding. However, as the density of the low sound velocity layer deposited by CVD is low, there may be a defect in that the sound velocity is low and the loss is high.

Therefore, in order to solve the defect problem, the surface acoustic wave device according to an embodiment of the present invention may form a second low sound velocity layer 122, which has a relatively high density and high sound velocity compared to the low sound velocity layer 121, at a position close to the piezoelectric plate 130, and the admittance characteristics and Q characteristics measured from the device of the present invention are shown in FIG. 3B.

Referring 3B, the admittance and Q to FIG. characteristics measured from the surface acoustic wave device of the present invention including the first low sound velocity layer 121 and the second low sound velocity layer 122 are shown as the red graph, and the black graph shows the characteristics of a case including the single-layer low sound velocity layer deposited by CVD also shown in FIG. 3A. The device of FIG. 3B specifically includes a first low sound velocity layer 121 deposited by CVD and a second low sound velocity layer 122 deposited by PVD to have a velocity relatively higher than that of the first low sound velocity layer 121, and through this, increase in the resonance frequency and improvement of the Q value can be confirmed.

In addition to the effect of improving the resonance frequency and Q value described above, owing to the two-layer low sound velocity layer structure (especially containing SiO₂) of the first low sound velocity layer 121 and the second low sound velocity layer 122, it is possible to improve bonding strength and enhance reliability of the surface acoustic wave device by adopting a bonding structure of the first low sound velocity layer 121 and the second low sound velocity layer 122, instead of a bonding structure between LiTaO₃ of the piezoelectric plate 130 having a low bonding strength and SiO₂ of the low sound velocity layer.

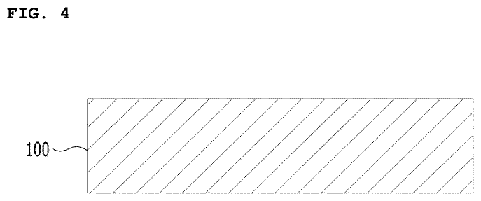

FIGS. 4 to 9 are views for explaining a method of manufacturing a surface acoustic wave device including two or more low sound velocity layers according to an embodiment of the present invention. The improvement effect compared to a conventional structure is also explained.

Referring to FIG. 4, a support substrate 100 made of Si is prepared. The support substrate 100 may include a silicon substrate, and may also include a sapphire or quartz substrate.

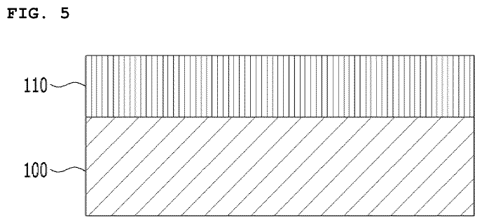

Referring to FIG. 5, the high sound velocity layer 110 may be deposited on the support substrate 100. Depositing the high sound velocity layer 110 may include, for example, forming PolySi using a CVD device or the like, and in some embodiments, the high sound velocity layer 110 may be made of amorphous silicon (aSi), SiN, AlN, BN, diamond, or the like, in addition to PolySi.

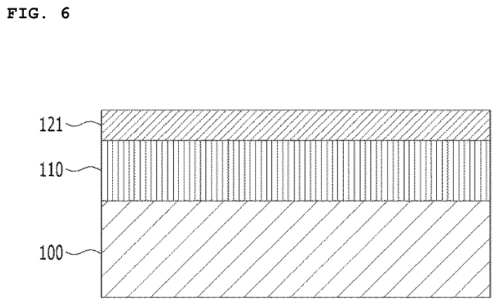

Referring to FIG. 6, the first low sound velocity layer 121 is formed on the high sound velocity layer 110. Forming the first low sound velocity layer 121 may include, for example, depositing SiO₂ using a CVD device. When the high sound velocity layer 110 is not deposited as shown in FIG. 3B, the first low sound velocity layer 121 is formed on the support substrate 100.

The CVD device may easily increase the deposition rate and lower wafer manufacturing costs compared to a sputter device.

In some embodiments of the present invention, the surface of the first low sound velocity layer 121 may be polished using Chemical Mechanical Polishing (CMP), ion milling, or the like to lower the roughness of the surface to facilitate wafer bonding.

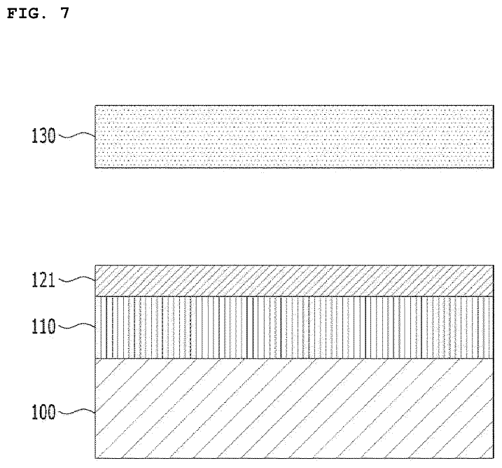

Referring to FIG. 7, a piezoelectric plate 130 containing single crystal LT or LN is prepared.

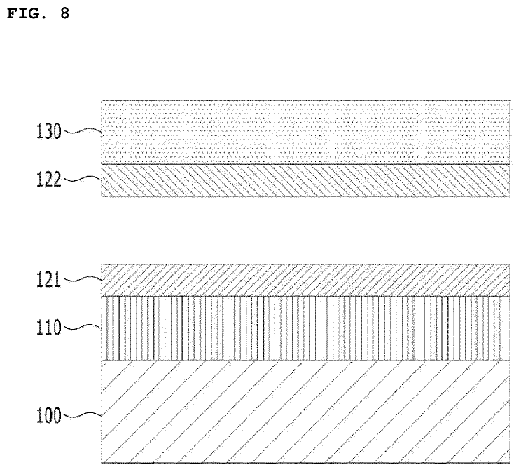

Referring to FIG. 8, the second low sound velocity layer 122 is formed on one side of the piezoelectric plate 130. Forming the second low sound velocity layer 122 may include, for example, depositing a film using SiO₂ the same as that of the first low sound velocity layer 121 using a sputtering device. Of course, here, the second low sound velocity layer 122 may be formed, as described above, to have physical properties different from those of the first low sound velocity layer 121 to have a sound velocity different from that of the first low sound velocity layer 121.

Meanwhile, in some embodiments of the present invention, the second low sound velocity layer 122 may be formed by depositing SiO₂ on one side of the piezoelectric plate 130 through a sputtering process. LiTaO₃ makes the CVD deposition difficult at a high temperature due to its pyroelectricity and Curie temperature, and deposition is mainly performed at a temperature of about 250° C. to 400° C. In the case of low-temperature deposition, the productivity is high, the density of SiO₂ is low, and the viscosity is high. Accordingly, when a CVD device deposits the second low sound velocity layer 122, it is desirable to thinly deposit the second low sound velocity layer 122.

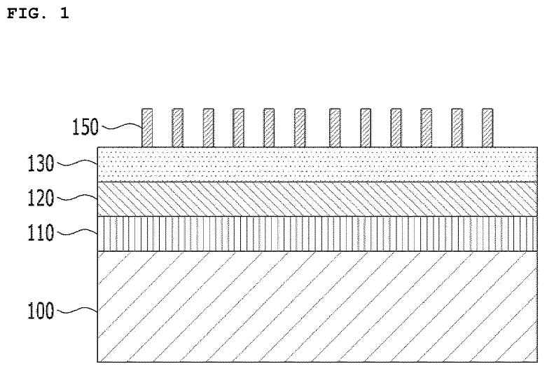

In addition, the sound velocity of the second low sound velocity layer 122 deposited using a sputter device may be higher than that of the first low sound velocity layer 121 deposited using a CVD device, and the viscosity may be lower. According to the structure of the prior art of FIG. 1, as the low sound velocity layer 120 is formed using a CVD device, compared to a case of having a high viscosity, the low viscosity of the second low sound velocity layer of this embodiment may prevent deterioration of Q performance.

Meanwhile, although a case of two low sound velocity layers such as the first low sound velocity layer 121 and the second low sound velocity layer 122 has been described in the surface acoustic wave device according to an embodiment of the present invention, even when three or more low sound velocity layers are included, i.e., when one or more low sound velocity layers are included between the first low sound velocity layer 121 and the second low sound velocity layer 122, the effect may be the same.

In some embodiments of the present invention, the surface of the second low sound velocity layer 122 may be polished using CMP, ion milling, or the like to lower the roughness of the surface to facilitate wafer bonding.

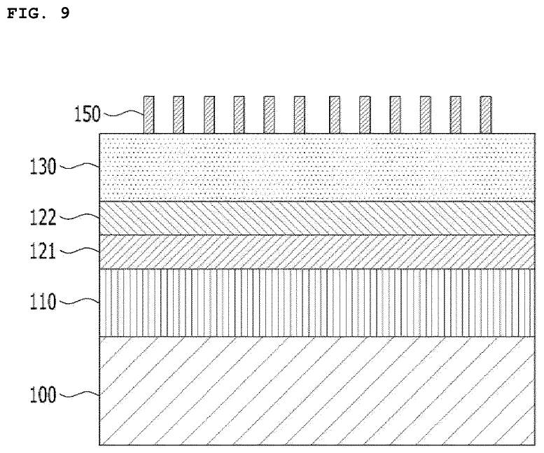

Referring to FIG. 9, the first low sound velocity layer 121 and the second low sound velocity layer 122 are bonded. In some embodiments of the present invention, thickness of the piezoelectric plate 130 after the bonding process may be set to 1.5 wavelength or less of the surface acoustic wave propagating to the piezoelectric plate.

Although the embodiments of the present invention have been described above with reference to the accompanying drawings, those skilled in the art may understand that the present invention can be implemented in other specific forms without changing the technical spirit or essential features. Therefore, the embodiments described above should be understood in all respects as illustrative and not restrictive.

### DESCRIPTION OF SYMBOLS

100: Support substrate
110: High sound velocity layer
120: Low sound velocity layer
121: First low sound velocity layer
122: Second low sound velocity layer
130: Piezoelectric plate
150: IDT electrode fingers

What is claimed is:

1. A surface acoustic wave device comprising:
a support substrate;
a first low sound velocity layer formed directly or indirectly on the support substrate;
at least one second low sound velocity layer formed on the first low sound velocity layer;
a piezoelectric plate formed on the second low sound velocity layer; and
a plurality of IDT electrode fingers formed on the piezoelectric plate, wherein
a sound velocity of the first low sound velocity layer and a sound velocity of the second low sound velocity layer are different from each other.

2. The device according to claim 1, wherein the first low sound velocity layer and the second low sound velocity layer include the same material.

3. The device according to claim 2, wherein the first low sound velocity layer and the second low sound velocity layer include an SiO₂ material.

4. The device according to claim 1, wherein the second low sound velocity layer has a sound velocity higher than that of the first low sound velocity layer.

5. The device according to claim 1, wherein the second low sound velocity layer has a density higher than that of the first low sound velocity layer.

6. The device according to claim 1, wherein the second low sound velocity layer has stiffness higher than that of the first low sound velocity layer.

7. The device according to claim 1, wherein the second low sound velocity layer has an O content higher than that of the first low sound velocity layer.

8. The device according to claim 1, wherein a resonance frequency of the surface acoustic wave is determined by a wavelength λ defined by a pitch of the IDT electrode fingers.

9. The device according to claim 8, wherein thickness of the piezoelectric plate is 1.5 times or less than the wavelength.

10. The device according to claim 1, wherein the first low sound velocity layer is formed by Chemical Vapor Disposition (CVD), and the second low sound velocity layer is formed by Physical Vapor Disposition (PVD).

11. The device according to claim 1, further comprising one or more low sound velocity layers between the first low sound velocity layer and the second low sound velocity layer.
